(19) United States
(12) Patent Application Publication
(10) Pub. No.: US 2009/0305504 A1
(43) Pub. Date: Dec. 10, 2009

(54) SINGLE PRECURSORS FOR ATOMIC LAYER DEPOSITION

(76) Inventors: Ce Ma, San Diego, CA (US); Qing Min Wang, North Andover, MA (US)

Correspondence Address: The BOC Group, Inc., 575 MOUNTAIN AVENUE, MURRAY HILL, NJ, 07974-2082, US

(21) Appl. No.: 12/374,343

(22) PCT Filed: Jul. 2, 2007
(86) PCT No.: PCT/US07/15407

§ 371 Date: Jun. 25, 2009

Related U.S. Application Data
(60) Provisional application No. 60/832,559, filed on Jul. 21, 2006.

(51) Int. Cl. H01L 21/3205; C07F 19/00; C07F 7/28; C07F 5/06; H01L 21/31

(52) U.S. Cl. 438/680; 556/42; 556/51; 556/54; 556/181; 556/182; 438/778; 257/E21.24; 257/E21.295

(57) ABSTRACT

Single precursors for use in flash ALD processes are disclosed. These precursors have the general formula:

XₘM(OR)ₙ or XₚM(O₂R′)_{q}

where M is Hf, Zr, Ti, Al, or Ta; X is a ligand that can interact with surface hydroxyl sites; OR and O₂R′ are alkoxyl groups with R and R′ containing two or more carbon atoms; m+n=3 to 5; p+2q=3 to 5; and m, n, p, q≠0. Further precursors have the general formula:

(R¹₂N)ₘM(═NR²)ₙ or (R³CN₂R⁴₂)ₚM(═NR²)_{q}

where M is Hf, Zr, Ti, or Ta; R¹₂N is an amino group with R¹ containing two or more carbon atoms; NR² is an imido group with R² containing two or more carbon atoms; R³ and R⁴ are alkyl groups; m+2n=4 or 5; p+2q=4 or 5; and m, n, p, q≠0. Flash ALD methods using these precursors are also described.

### CROSS REFERENCE TO RELATED APPLICATIONS

This application claims priority from international Application Serial No. PCT/US2007/015407, filed 2 Jul. 2007 (published as WO 2008/013659 A2, with publication date 31 Jan. 2008), which claims priority from U.S. Application No. 60/832,559 filed 21 Jul. 2006.

### FIELD OF THE INVENTION

The present invention relates to new and useful precursors for atomic layer deposition.

### BACKGROUND OF THE INVENTION

Atomic layer deposition (ALD) is an enabling technology for next generation conductor barrier layers, high-k gate dielectric layers, high-k capacitance layers, capping layers, and metallic gate electrodes in silicon wafer processes. ALD has also been applied in other electronics industries, such as flat panel display, compound semiconductor, magnetic and optical storage, solar cell, nanotechnology and nanomaterials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

As semiconductor devices continue to get more densely packed with devices, channel lengths also have to be made smaller and smaller. For future electronic device technologies, such as 90 nm technology, it will be necessary to replace SiO₂ and SiON gate dielectrics with ultra thin high-k oxides having effective oxide thickness (EOT) less than 1.5 nm. Preferably, high-k materials should have high band gaps and band offsets, high k values, good stability on silicon, minimal SiO₂ interface layer, and high quality interfaces on substrates. Amorphous or high crystalline temperature films are also desirable. Some acceptable high-k dielectric materials include, HfO₂, Al₂O₃, ZrO₂, and the related ternary high-k materials have received the most attention for use as gate dielectrics. HfO₂ and ZrO₂ have higher k values but they also have lower break down fields and crystalline temperatures. The aluminates of Hf and Zr possess the combined benefits of higher k values and higher break down fields.

A typical ALD process uses sequential precursor gas pulses to deposit a film one layer at a time. In particular, a first precursor gas is introduced into a process chamber and produces a monolayer by reaction at surface of a substrate in the chamber. A second precursor is then introduced to react with the first precursor and form a monolayer of film made up of components of both the first precursor and second precursor, on the substrate. Between each precursor pulse, the chamber is normally purged using an inert gas. Each pair of pulses (one cycle) produces a monolayer of film in a self-limited manner. This allows for accurate control of final film thickness based on the number of deposition cycles performed.

However, current ALD processes suffer from low growth rate, the need for high deposition temperatures, precursor decomposition and side gas phase reactions. The more stable ALD precursors, such as halides, often require high deposition temperatures that exceed the thermal budget of the substrate. The use of metalorganic precursors can reduce the deposition temperatures, but thermal decomposition becomes a serious issue.

There remains a need in the art for new types of ALD precursors.

### SUMMARY OF INVENTION

The present invention provides single ALD precursors of a metal oxide that are suitable for flash ALD processes. In particular, the present invention provides single ALD precursors having the general formula:

XₘM(OR)ₙ or XₚM(O₂R′)_{q}

where M is Hf, Zr, Ti, Al, or Ta; X is a ligand that can interact with surface hydroxyl sites; OR and O2R′ are alkoxyl groups with R and R′ containing two or more carbon atoms; m+n 3 to 5; p+2q=3 to 5; and m, n, p, q≠0The present invention also includes single ALD precursors having the general formula:

(R¹₂N)ₘM(═NR²)ₙ or (R³CN₂R⁴₂)ₚM(═NR²)_{q}

where M is Hf, Zr, Ti, or Ta; R¹₂N is an amino group with R¹ containing two or more carbon atoms; NR² is an imido group with R² containing two or more carbon atoms; R³ and R⁴ are alkyl groups; m+2n=4 or 5; p+2q=4 or 5; and m, n, p, q≠0.

### DETAILED DESCRIPTION OF THE INVENTION

The present invention provides single ALD precursors of a metal oxide that are suitable for flash ALD processes. In particular, the present invention provides single ALD precursors having the general formula:

XₘM(OR)ₙ or XₚM(O₂R′)_{q}

where M is Hf, Zr, Ti, Al, or Ta; X is a ligand that can interact with surface hydroxyl sites; OR and O₂R′ are alkoxyl groups with R and R′ containing two or more carbon atoms; m+n=3 to 5; p+2q=3 to 5; and m, n, p, q≠0. In particular, the X ligand may be Cl, Br, I, or CH3. In further embodiments of the present invention, R and R′ may contain other organic groups such as CF3, t-butyl, SiMe3, or halogen atoms substituted for the hydrogen atoms. In addition, R and R′ may be linear, branched or cyclic structures designed to absorb certain radiation energy. The general structure of the precursors according to this invention is shown as follows:

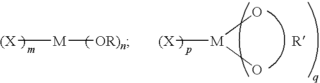

The precursors according to the present invention are suitable for flash ALD processes that can be carried out in a system comprising a single precursor source delivery system, a wafer chamber, a flash radiation source, and an exhaust vacuum system. The flash radiation source includes but is not limited to photons, electrons, positrons, and particles. For example, a flash photon source can be either filtered lamps or lasers on the top of the chamber lid. The wavelength of flash photon is selected for dissociation of the target bonds and can vary from 150 nm to 900 nm. The flash source can cover a large surface area. The photo-energy converts to chemical energy of adsorbed molecule on the surface.

For example, to dissociate C—O bond of an adsorbed molecule without breaking the metal-oxygen bond, a wavelength in the range of 250 nm to 340 nm is selected. After the C—O bond is photolytically cleaved, the O— atom of the adsorbed radical becomes a reactive base and excited R* is generated from the cleaved R radical. Then a hydrogen atom or a hydrogen atom with a halogen atom renews the OH sites by bonding with the O— base. This allows for a double bonded R′ to be formed, that can be pumped away. Further cycles can be performed to build up the deposited layer. This scheme is shown below.

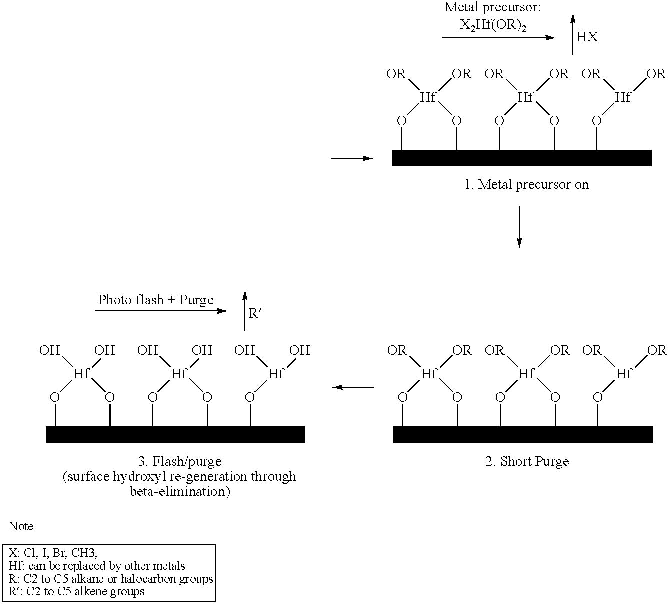

The present invention can also be applied to metal and metal nitride film deposition. For metal nitride films, the single precursors of the present invention have the general formula:

(R¹₂N)ₘM(═NR²)ₙ or (R³CN₂R⁴₂)ₚM(═NR²)_{q}

where M is Hf, Zr, Ti, or Ta; R¹₂N is an amino group with R¹ containing two or more carbon atoms; NR² is an imido group with R² containing two or more carbon atoms; R³ and R⁴ are alkyl groups such as CH₃, CF₃, t-butyl or SiMe₃ that are used to increase the volatility of the complex; m+2n=4 or 5; p+2q=4 or 5; and m, n, p, q≠0. Precursors according to this embodiment of the present invention have the general structure below:

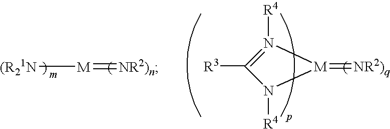

Using a flash photon, it is possible to dissociate the metal nitrogen and C—N single bonds while leaving the metal nitrogen double bond in tact. This then allows for continued layer growth through application of further ALD cycles. This scheme is shown as follows.

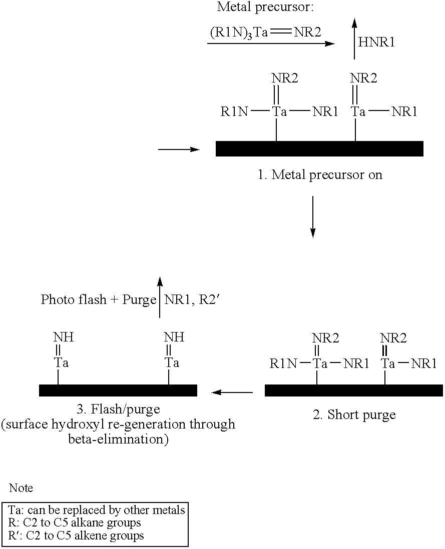

In order to achieve uniform growth in an ALD process, it is necessary to expose all surfaces, i.e., the bottom and sidewalls of trenches and vias, to radiation rays. For flash ALD, this can be easily accomplished by using a diffusion plate between the source and the wafer. Because the dimensions of the wafer structure are so small compared to the chamber dimensions, only a very small diverging angle is needed to reach all surfaces with the same stroke of the same radiation source. In particular, a diverging angle of sin-1 (d/2 L), where d is the width of the trench or via in the wafer and L is distance from light source is adequate. For example, for a trench having a width of 100 nm located 50 mm from the light source, the diverging angle is 5.7E-5 degrees. This is so small, that the natural divergence of a uniform source is generally capable of exciting the adsorbed species on all exposed horizontal and vertical surfaces.

The precursors according to the present invention provide a number of advantages). In particular, the present invention is fundamentally different from traditional photo-assisted CVD processes. In photo-assisted CVD, precursors are excited in vapor or gas phase and become more reactive, enabling film growth at lower temperatures and higher rates. However, vapor phase radicals can also coat optical source surfaces, making cleaning of the optical source surface a significant issue for photo-assisted CVD processes. Conversely, in a flash ALD process, radiation rays, including photons, interact with adsorbed precursors on the reactive surface, nearly eliminating coating of optical source surfaces.

In addition, as noted above, purging is required between precursors in traditional ALD processes. By using the single precursors of the present invention in a flash ALD, significant time savings can be achieved. This is because the flash source is turned on after only a very short delay and shorter purge times are necessary. The actual saving in cycle time is 45% as shown in Table 1 below. Because of this cycle time savings, film growth rate can be increased by nearly 50%.

TABLE 1
Process Time Comparison

| | Precursor | | Precursor | | |
|---|---|---|---|---|---|
| | 1 | Purge 1 | 2 | Purge 2 | Total |
| Process | (seconds) | (seconds) | (seconds) | (seconds) | (seconds) |
| Standard | 2 | 2 | 2 | 2 | 8 |
| ALD Two | | | | | |
| precursors | | | | | |
| Flash ALD | 2 | 0.4 | 0 | 2* | 4.4 |
| Single | | | | | |
| precursor | | | | | |

| | |
|---|---|
| Cycle Time Savings | 45% |

*light flash and purge

Moreover, by using the single precursors of the present invention, unwanted gas phase reactions are avoided and the overall cost of equipment can be reduced. In particular, typical ALD processes require two highly reactive precursors that must be isolated from each other in vapor phase in the delivery system, deposition chamber, and the exhaust system to assure the unwanted gas phase reactions do not occur. Using the single precursors of the present invention means that the gas phase reactions cannot occur and the system can be designed without the isolation means. This results in a significantly lower cost system as well as extending the life of the system between necessary cleanings and maintenance.

The single precursors of the present invention also require lower operating temperatures than those needed in traditional ALD processes. In a standard ALD process, film growth requires deposition temperatures as high as 500° C. in order to generate high purity thin films. When using the single precursors of the present invention, substrate temperatures from 50° C. to 300° C. are preferred. These lower temperatures are possible because of the ability to select the photo energy necessary to dissociate the target bond and renew the surface for the next precursor cycle. For example, as noted above, C—O bonds can be eliminated and —OH terminated surfaces generated by selecting a wavelength in the range of 250 nm to 340 nm.

Further, because of the lower temperature deposition, thermal decomposition of the precursors can be reduced. Thermal decomposition of alkoxide ligands is also avoided. This assures self-limiting growth because the ligand forms a protective cap layer. The thin film can grow only when the ligand cap is removed in the flash process.

It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. Precursors for atomic layer deposition having the formula:
XₘM(OR)ₙ, or XₚM(O₂R′)_{q}
where M is Hf, Zr, Ti, Al, or Ta; X is a ligand that can interact with surface hydroxyl sites; OR and O₂R′ are alkoxyl groups with R and R′ containing two or more carbon atoms; m+n=3 to 5; p+2q=3 to 5; and m, n, p, q≠0.

2. Precursors according to claim 1, wherein X is Cl, Br, I, or CH3.

3. Precursors according to claim 1, wherein R and R′ contain CF3, t-butyl, SiMe3, or halogen atoms substituted for the hydrogen atoms.

4. Precursors according to claim 1, wherein R and R′ are linear, branched or cyclic structures.

5. Precursors for atomic layer deposition having the formula:
(R¹₂N)ₘM(═NR²)ₙ or (R³CN₂R⁴₂)ₚM(═NR²)_{q}
where M is Hf, Zr, Ti, or Ta; R¹₂N is an amino group with R¹ containing two or more carbon atoms; NR² is an imido group with R² containing two or more carbon atoms; R³ and R⁴ are alkyl groups; m+2n=4 or 5; p+2q=4 or 5; and m, n, p, q≠0.

6. Precursors according to claim 5, wherein the alkyl groups are CH₃, CF₃, t-butyl or SiMe₃.

7. A flash ALD method comprising:
providing a single precursor to a deposition chamber, the precursor having the formula
XₘM(OR)ₙ or XₚM(O₂R′)_{q}
where M is Hf, Zr, Ti, Al, or Ta; X is a ligand that can interact with surface hydroxyl sites; OR and O₂R′ are alkoxyl groups with R and R′ containing two or more carbon atoms; m+n=3 to 5; p+2q=3 to 5; and m, p, q≠0;
reacting the precursor with a substrate surface in the deposition chamber;
radiating the substrate surface to dissociate C—O bonds and renew OH sites; and
repeating until a desired film thickness is achieved.

8. A flash ALD method according to claim 7, wherein radiating the substrate comprises radiating with photons, electrons, positrons, or particles.

9. A flash ALD method according to claim 7, wherein radiating the substrate comprises radiating at a wavelength from 150 nm to 900 nm.

10. A flash ALD method according to claim 9, wherein the wavelength is from 250 nm to 340 nm.

11. A flash ALD method comprising:
providing a single precursor to a deposition chamber, the precursor having the formula
(R¹₂N)ₘM(═NR²)ₙ or (R³CN₂R⁴₂)ₚM(═NR²)_{q}
where M is Hf, Zr, Ti, or Ta; R¹₂N is an amino group with R¹ containing two or more carbon atoms; NR² is an imido group with R² containing two or more carbon atoms; R³ and R⁴ are alkyl groups; m+2n=4 or 5; p+2q=4 or 5; and m, n, p, q≠0.
reacting the precursor with a substrate surface in the deposition chamber;
radiating the substrate surface to dissociate metal nitrogen and C—N single bonds but leaving metal nitrogen double bonds in tact; and
repeating until a desired film thickness is achieved.

12. A flash ALD method according to claim 7, wherein radiating the substrate comprises radiating with photons, electrons, positrons, or particles.

13. A flash ALD method according to claim 7, wherein radiating the substrate comprises radiating at a wavelength from 150 nm to 900 nm.
